(19) United States
(12) Patent Application Publication
(10) Pub. No.: US 2022/0069211 A1
(43) Pub. Date: Mar. 3, 2022

(54) SMALL LINE OR PILLAR STRUCTURE AND PROCESS

(71) Applicant: MACRONIX INTERNATIONAL CO., LTD., HSINCHU (TW)

(72) Inventors: Hsiang-Lan LUNG, Ardsley, NY (US); Chiao-Wen YEH, New Taipei City (TW)

(73) Assignee: MACRONIX INTERNATIONAL CO., LTD., HSINCHU (TW)

(21) Appl. No.: 17/011,399

(22) Filed: Sep. 3, 2020

(51) Int. Cl. H01L 45/00; H01L 27/24

(52) U.S. Cl. CPC H01L 45/1233; H01L 27/2481

(57) ABSTRACT

A pillar-shaped structure and a line-shaped structure are described that include a supporting top conductive layer, an active material layer, such as a memory material or switching material, and a bottom conductive layer. The active material layer is more narrow than the supporting top conductive layer. A supporting side insulating layer is formed connecting the top and bottom conductive layers to provide structure stability. A void, or air gap, is formed between the active material layer and the supporting side insulating layer, which can provide improved thermal isolation between adjacent pillar-shaped or line-shaped structures.

### BACKGROUND

### Field

The present invention relates to a pillar-shaped or line-shaped structure having a narrow active layer on integrated circuits, such as a pillar-shaped memory cell, and a method of manufacturing the same.

### Description of Related Art

Pillar-shaped structures are being deployed in integrated circuits for a variety of purposes, including for the formation of memory cells. Pillar-shaped memory cells, and other types of pillar-shaped cells can comprise a stack including a first electrode, an active layer such as a memory material or a switch material, and a second electrode. It can be desirable to form an active layer as small as possible to reduce power consumption and enable higher layout density. However, as the diameter of these pillar-shaped structures scales downward, they become fragile in the manufacturing process. In some cases, these pillar-shaped structures can fall down during the manufacturing process, or otherwise be damaged, causing low yield in the manufacturing. Similar problems arise in the formation of narrow line-shaped stacks.

It is desirable to provide a stable pillar or line structure, with small dimensions in the active layer, along with manufacturing processes, enabling higher yield in the manufacturing.

### SUMMARY

A pillar-shaped structure and a line-shaped structure are described that include a supporting top conductive layer, an active material layer, such as a memory material or switching material, and a bottom conductive layer. The active material layer is more narrow than the supporting top conductive layer. A supporting side insulating layer is formed connecting the top and bottom conductive layers to provide structure stability. A void, or air gap, is formed between the active material layer, and the supporting side insulating layer, which can provide improved thermal isolation between adjacent pillar-shaped or line-shaped structures.

A manufacturing method is described for a line-shaped or pillar-shaped structure. This method can include forming a pillar-shaped or line-shaped stack including a first conductor layer, an active material layer, and a second conductor layer in electrical series. This method of formation can include forming blanket layers, and then etching the blanket layers using a single lithographic pattern to form pillars or lines in which the second conductor layer and the active material layer have aligned sides. Then, a selective lateral etch can be used, such as a selective isotropic etch, removing the active material on the sides of the pillar or line to form an undercut area between the second conductor layer and the first conductor layer. This results in a laterally-etched active material layer that is trimmed, and as a result, more narrow than the second conductor layer in the stack. The undercut area is then sealed between the second conductor layer and the first conductor layer by a nonconformal deposition of an insulating material. This nonconformal deposition can result in formation of an insulating seal between the first and second conductor layers, and an insulating void in the undercut area enclosed between the first and second conductor layers by the insulating material.

Embodiments are described in which the selective lateral etch and the nonconformal deposition of the insulating material are performed in situ, in a single process chamber, and in some embodiments using an etch/deposition chemistry that etches the active material and deposits the insulating material in a manner that results in the structure described. Alternatively, these processes can be performed separately.

Embodiments are described in which the active material layer comprises a chalcogenide and the first and second conductor layers comprise conductive material resistant to the selective lateral etch. The active material layer can comprise a memory material, such as materials used in resistive random access memory RRAM, magneto-resistive random access memory MRAM and ferro-electric random access memory FeRAM. Embodiments are described in which the active material layer comprises a switching material. Embodiments are described in which there is a plurality of active layers in the pillar or line, each more narrow than the conductive layer overlying them, and surrounded by a supporting, and insulating, seal.

Other aspects and advantages of the present invention can be seen on review of the drawings, the detailed description and the claims, which follow.

### BRIEF DESCRIPTION OF THE DRAWINGS

FIG. 1 is a simplified cross-section of a pillar or line structure including a narrow active layer, and an insulating support structure in an undercut region.

FIGS. 2, 3, 4 and 5 illustrate stages and manufacturing of a pillar or line structure as described herein.

FIG. 6 is a simplified cross-section of a pillar or line structure including multiple narrow active layers.

FIG. 7 is a simplified flowchart for a manufacturing method as described herein.

FIG. 8 is a block diagram of an integrated circuit memory device including stable pillar memory cells as described herein.

### DETAILED DESCRIPTION

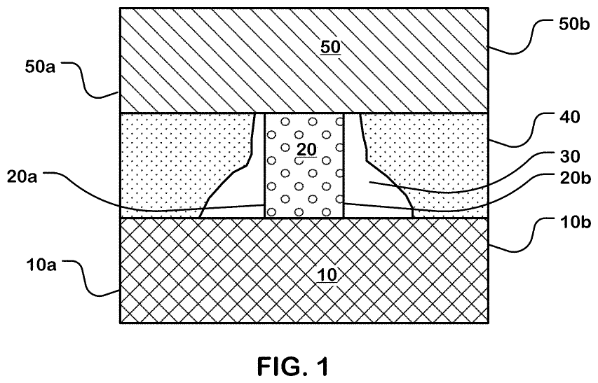

A detailed description of embodiments of the present invention is provided with reference to the FIGS. 1-8.

FIG. 1 shows a cross-section of a pillar or line structure. The structure includes a stack having a bottom electrode 10, an active material layer 20, and a top electrode 50. The bottom electrode 10 and the top electrode 50 are conductor layers, which act as electrodes because they have surfaces directly in contact the active material layer 20.

In this embodiment, the sidewalls 10a and 10b of the bottom electrode 10 and the sidewalls 50a and 50b of the top electrode 50 are aligned. The outside surfaces, sidewalls 20a and 20b, of the active material layer are recessed relative to the outside surfaces, sidewalls 50a and 50b, of the top electrode 50, forming an undercut region.

The active material layer 20 is surrounded by a void 30 in the undercut region, enclosed by insulating support material 40, which extends between the upper surface of the bottom electrode 10 and the lower surface of the top electrode 50 in the undercut region.

In embodiments in which the structure is pillar-shaped, the void can completely surround the active material layer 20. In embodiments in which the structure is line-shaped, the void extends along the sides of the active material layer 20, along at least a portion of the length of the line.

The first and second electrodes 10, 50 comprise conductor materials such as Carbon, TiN or TaN. Alternatively, the first and second electrodes 10, 50 may each be W, WN, TiAlN or TaAlN, or comprise, for further examples, one or more elements selected from the group consisting of doped-Si, Si, Ge, Cr, Ti, W, Mo, Al, Ta, Cu, Pt, Ir, La, Ni, N, O, and Ru and combinations thereof. The conductor material used can be the same, or different, for the first and second electrodes. The conductor materials can be selected based on a combination of factors, including for embodiments described herein, their etching speed relative to the active material, for the etch process used as the selective lateral etch.

The active material layer 20 can comprise a chalcogenide, including chalcogenides used in phase change memory material or chalcogenides used as ovonic threshold switch material. Also, the active material layer can be other types of programmable resistance materials, such as other phase change materials, transition metal oxides, magnetoresistive materials, ferroelectric memory materials and so on.

The insulating support material can comprise silicon nitride, silicon oxide, silicon oxynitride, or other compatible insulating materials.

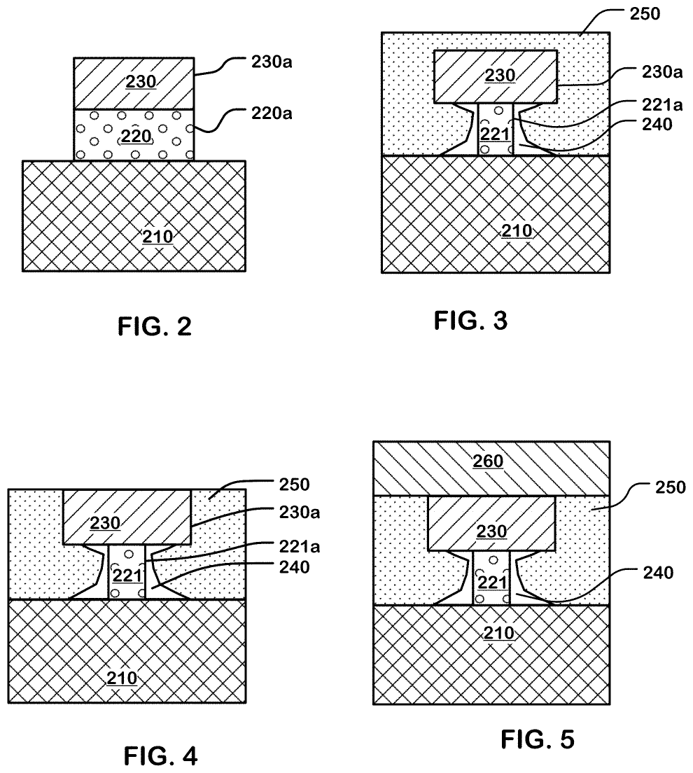

FIGS. 2-5 illustrate stages in a manufacturing process, which can have higher yield along with narrow active material layers as described herein.

FIG. 2 illustrates a stage during manufacturing after formation of a plug 210, or other conductor element, on an integrated circuit substrate. For example, the plug 210 can comprise a tungsten plug formed as a via through a layer of dielectric material, providing for electrical connection to an underlying substrate which may include access circuitry, such as transistors, diodes, word lines or bit lines. The plug 210 can act as a first conductor layer for the pillar-shaped or line-shaped structure. Also, to form the structure illustrated at this stage, a blanket layer of active material and a blanket second conductor layer are formed sequentially above the substrate, and then patterned to form the pillar-shaped or line-shaped stack comprising active material layer 220 and the second conductor layer 230 on the plug 210. This structure can be patterned using a single lithographic mask with anisotropic etching procedures, so that the sidewalls 220a, 230a of the active material layer 220 and of the conductor layer 230 are aligned. For example, using a titanium nitride as the top conductor layer 230, and a chalcogenide, like Ge₂Sb₂Te₅ (GST) as the active layer, a recipe for anisotropic etch of TiN can be reactive ion etching with Cl₂, Ar and CHF₃, using etch parameters like:

Source power: 500 W. (Watt)

Substrate power: 75 W.

Pressure: 4 mTorr

Gas flow rate of Chlorine: 30 sccm. (standard cubic centimeters per minute)

Gas flow rate of Argon:130 sccm.

Gas flow rate of Fluoroform: 15 sccm.

Process temperature: 65 degree Celsius.

A recipe for the anisotropic etch of GST, can be reactive ion etching with Ar, using etch parameters like:

Source power: 500 W. (Watt)

Substrate power: 200 W.

Pressure: 4 mTorr

Gas flow rate of Argon:130 sccm.

Process temperature: 65 degree Celsius.

FIG. 3 illustrates a later stage during manufacturing, after applying a selective lateral etch, which selectively etches the active material layer 220 to form a more narrow layer 221 of active material to form and undercut the area between the second conductor layer 230 and the plug 210. Also, an insulating material 250 is deposited, filling the region surrounding the line or pillar. During deposition, the insulating material 250 extends part way into the undercut area, while leaving void 240 between the insulating material and the outer surface 221a of the layer 221 of active material.

The selective lateral etch and the deposition of insulating material can be executed in situ, in a single process chamber using a recipe for GST etch/silicon nitride deposition like:

Source power: 2800 W. (Watt)

Substrate power: 0 W.

Pressure: 150 mTorr

Gas flow rate of H₂: 103 sccm.

Gas flow rate of N₂:25 sccm.

Gas flow rate of Argon:350 sccm.

Gas flow rate of SiH₄:30 sccm.

Process temperature: 60 degree Celsius.

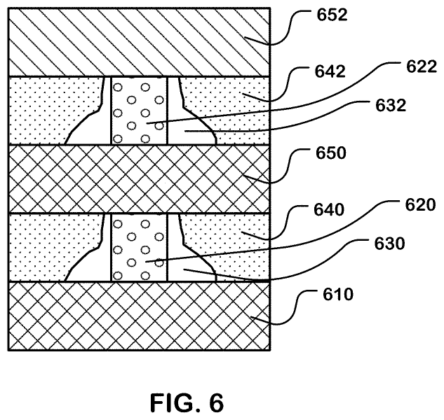

Chalcogenide materials in general have a faster etch rate than electrode materials such as Ti, TiN, W, . . . or C, in various chemistries (HBr, Cl₂, F, . . . or Ar). This makes the intentional undercutting of an electrode-chalcogenide stack possible. It works also for a more complex structure like the one in the embodiment which is electrode-chalcogenide-electrode-chalcogenide-electrode (e.g. FIG. 6).

In this RIE process, the GST will be undercut because TiN has much lower reactivity with these gases. In an undercut profile, air gap will be naturally formed with deposition of any CVD SiNx (or other dielectrics) that is not perfectly conformal. The deposition rates at the field region, including the top of TiN and side of TiN, are faster because of the presence of more radicals and plasma in this region. On the other hand, the deposition is slower at the undercutting area. With the SiN deposition, the opening of the undercutting area will be pinched off gradually. The SiN deposition at the undercutting area will then slow down further, or end, due to lack of reactants. The air gap or void is then formed.

The air gap will be more pronounced if the GST is undercut deeper or with a smaller opening (which might be a result of thinner GST thickness). Also, a less conformal SiN deposition can pinch up the opening more quickly and form a bigger air gap.

FIG. 4 illustrates a stage in manufacturing after planarizing the top of the insulating material 250, and top conductor layer 230 in the line or pillar structure, using a process such as chemical mechanical polishing.

FIG. 5 illustrates a later stage in manufacturing after formation of a top conductor 260, such as a bit line or other access circuitry in contact with the top conductor layer 230.

In one example, a pillar-shaped structure having a diameter of about 55 nm formed using state-of-the-art lithography can be utilized. Using the techniques described herein, a layer of active material can have a reduced diameter to about 20 to 30 nm. This substantially improves the current density through the active material at any given current magnitude, and can reduce power requirements, increase speed, or enable other technologies. The pillar-shaped structure is particularly useful in memory cells, having small bodies of memory material, formed in a structure that is stable during manufacturing.

FIG. 6 illustrates an embodiment that includes multiple active layers. As illustrated, the stack includes a first conductor layer 610, a first active layer 620, a second conductor layer 650, a second active layer 622, and a third conductor layer 652.

The first conductor layer 610, first active layer 620 and second conductor layer 650 are in electrical series. The selective lateral etch forms a laterally etched, or trimmed, active area 620 and an undercut area between the second conductor layer 650 and the first conductor layer 610. The deposition of insulating material forms an insulating void 630 in the undercut area between the first conductor layer 610 and the second conductor layer 650, the insulating void being 630 enclosed by the insulating material forming an insulating support 640 between the first and second conductor layers.

The second active layer 622 and a third conductor layer 652 are in electrical series with the second conductor layer 650, and the selective lateral etch forms a second laterally-etched, or trimmed, active layer 622 and a second undercut area between the second conductor layer 650 and the third conductor layer 652, and the deposition of insulating material forms a second insulating void 632 in the second undercut area, the second insulating void being enclosed by the insulating material forming an insulating support 642 between the second and third conductor layers.

In this embodiment, the materials used as active layers can be the same or different. For example, one of the active layers may be a memory element, and the other of the active layers may be a switch element. Also, both active layers may be memory elements in some embodiments. Also, the materials used for the conductor layers can be the same or different.

When there are more than one chalcogenide materials in series, the intermediate conductor layers can be formed using carbon-based material. A carbon layer also works as a diffusion barrier to prevent two chalcogenides from intermixing during processing or operation. This role can be fulfilled by many metal layers.

A carbon layer can be favored as thermal insulator which helps heat confinement. This can lower the operation current required for an amorphization process (also known and RESET operation to bring GST to high resistance state). The nearby device unit (such as OTS) can be kept in low temperature during GST operation.

Also, carbon is a good etch buffer layer, which can be etched with inert gas N₂ which has a low etch rate for chalcogenides. This good selectivity allows good layer-by-layer etching and the chalcogenides are not altered after the etching process.

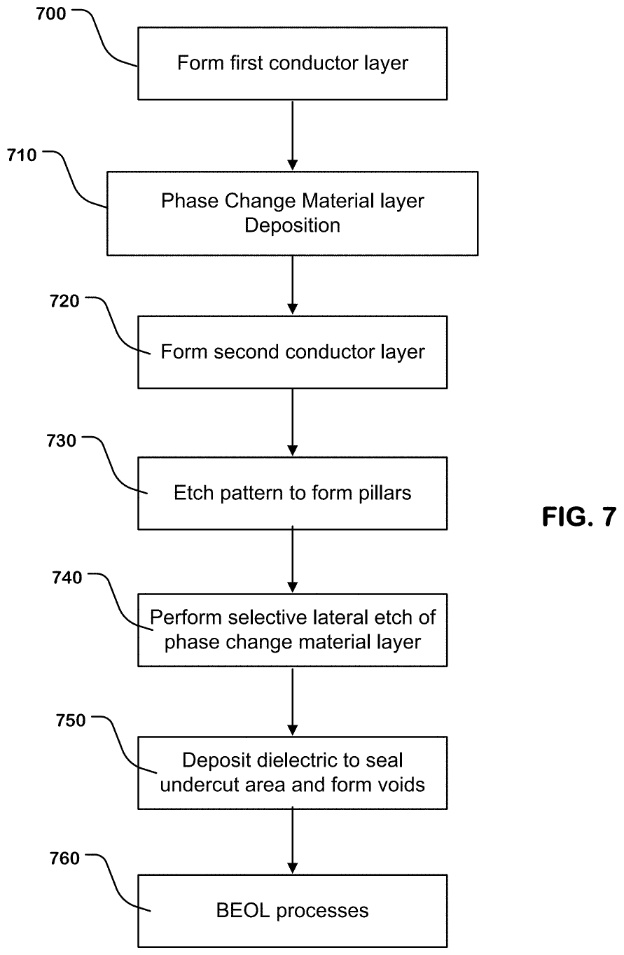

FIG. 7 illustrates a manufacturing process for manufacturing a memory cell having a pillar-shaped structure. A similar process can be applied to make line-shaped structures. In the first step, a first conductor layer is formed (700). As discussed above, the first conductor layer can be a plug or via arranged vertically relative to a substrate, or can be a layer of conductor material formed on a bit line or word line conductor, for example. The next illustrated step includes deposition of the phase change material layer, such as GST (710). The phase change material can be the active layer. In other embodiments, other types of active layer materials can be utilized. After deposition of the phase change material layer, a second conductor layer such as titanium nitride is deposited, which can act as a top electrode on the phase change material layer (720). The next step includes applying a process to pattern the layers of second conductive material and active material to form the pillars, which at this stage comprise a stack of a first conductor layer, an active layer, and the top second conductor layer (730). This patterning step can comprise depositing a hard mask material or coating over the second conductor layer, using lithography or another patterning technique to define the layout of the pillar, and then etching the titanium nitride using reactive ion etching, and the GST using reactive ion etching as discussed above to form a structure having aligned sides, or sides exposing the active material under the second electrode material. Also, in the process, a selective lateral etch of the phase change material layer is executed (740). The process also includes deposition of an insulating material to form a supporting seal in an undercut area left by the selective lateral etching beneath the second conductor layer in the pillar (750). As described above, the selective lateral etch, and the deposition of insulating material to form the seal and voids, and the supporting insulating structure can be performed in situ using a single chemistry that etches the active material and deposits the insulating material in a single process chamber. Thereafter, back end of line BEOL processes can be performed (760) such as the chemical mechanical polishing described above, and the formation of other circuit elements and conductor lines overlying the pillar shaped memory cells. The BEOL processes can be standard processes as known in the art, and the processes performed depend upon the configuration of the chip in which the memory cell is implemented. Generally, the structures formed by BEOL processes may include contacts, inter-layer dielectrics and various metal layers for interconnections on the chip including circuitry to couple the memory cell to periphery circuitry.

It will be appreciated that many of the steps of FIG. 7 can be combined, performed in parallel or performed in a different sequence without affecting the functions achieved. In some cases, as the reader will appreciate, a rearrangement of steps will achieve the same results only if certain other changes are made as well. In other cases, as the reader will appreciate, a rearrangement of steps will achieve the same results only if certain conditions are satisfied. Furthermore, it will be appreciated that the flow charts herein show only steps that are pertinent to an understanding of the technology and it will be understood that numerous additional steps for accomplishing other functions can be performed before, after and between those shown.

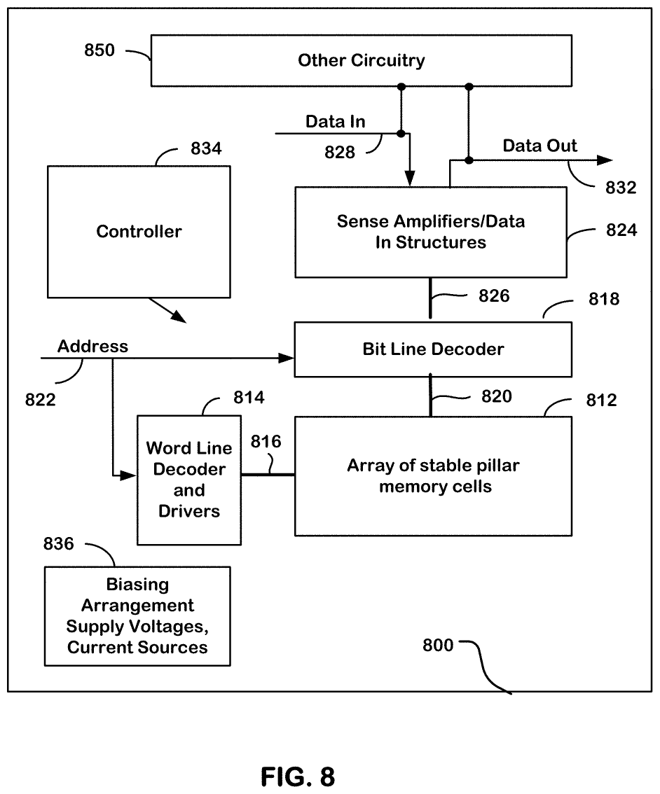

FIG. 8 is a simplified block diagram of an integrated circuit 800 including an array 812 of stable pillar-shaped memory cells as described herein, with programmable resistance memory. A row/level line decoder 814 having read, set and reset modes is coupled to, and in electrical communication with, a plurality of word lines 816 arranged in levels and along rows in the array 812. A column/level decoder 818 is in electrical communication with a plurality of bit lines 820 arranged in levels and along columns in the array 812 for reading, setting, and resetting the memory cells in the array 812. Addresses are supplied on bus 822 to row/level decoder 814 and column/level decoder 818. Sense circuitry (Sense amplifiers) and data-in structures in block 824, including voltage and/or current sources for the read, set, and reset modes are coupled to column/level decoder 818 via data bus 826. Data is supplied via a data-in line 828 from input/output ports on integrated circuit 800, or from other data sources internal or external to integrated circuit 800, to data-in structures in block 824. Other circuitry 850 may be included on integrated circuit 800, such as a general purpose processor or special purpose application circuitry, or a combination of modules providing system-on-a-chip functionality supported by array 812. Data is supplied via a data-out line 832 from the sense amplifiers in block 824 to input/output ports on integrated circuit 800, or to other data destinations internal or external to integrated circuit 800.

A controller 834, implemented in this example, using a bias arrangement state machine, controls the application of bias circuitry voltage sources and current sources 836 for the application of bias arrangements, including read, set, reset and verify voltages, and/or currents for the word lines and bit lines. The controller includes control circuitry configured for switching layers having a threshold voltage depending on the structure and composition of the memory cells, by applying a voltage to a selected memory cell so that the voltage on the switch in the select memory cell is above the threshold, and a voltage to an unselected memory cell so that the voltage on the switch in unselected memory cell is below the threshold during a read operation or other operation accessing the selected memory cell.

Controller 834 may be implemented using special-purpose logic circuitry as known in the art. In alternative embodiments, controller 834 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 834.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A method for manufacturing a pillar-shaped or line-shaped cell, comprising:
forming a stack including a first conductor layer, an active material layer, and a second conductor layer, a second active material layer and a third conductor layer in electrical series, wherein the second conductor layer and the active material layer have aligned sides;
performing a selective lateral etch of the active material layer to form a first undercut area between the second conductor layer and the first conductor layer, to provide a first laterally-etched active material layer; and
sealing the undercut area between the second conductor layer and the first conductor layer by non-conformal deposition of an insulating material, to form a first insulating void in the first undercut area, the first insulating void being enclosed between the first and second conductor layers by the insulating material; wherein the selective lateral etch forms a second laterally-etched active material layer and a second undercut area between the second conductor layer and the third conductor layer, and the deposition of the insulating material forms a second insulating void in the second undercut area, the second insulating void being enclosed by the insulating material between the second and third conductor layers.

2. The method of claim 1, wherein the insulating void in the undercut area surrounds the laterally-etched active material layer.

3. The method of claim 1, wherein the insulating void in the undercut area is surrounded by a portion of the insulating material within the undercut area between the first and second conductor layers.

4. The method of claim 1, wherein the first and second conductor layers comprise conductive material resistant to the selective lateral etch.

5. The method of claim 1, wherein the selective lateral etch and the non-conformal deposition of the insulating material are performed (in situ) in a single process chamber.

6. (canceled)

7. A pillar-shaped or line-shaped cell, comprising:
a stack including a first conductor layer, a first active material layer, a second conductor layer, a second active material layer and a third conductor layer in electrical series;
the first active material layer having an outside surface recessed relative to an outer side surface of the second conductor layer, leaving an undercut area between the second conductor layer and the first conductor layer; and
a first insulating seal enclosing a first insulating void in the undercut area, the first insulating void being enclosed between the first and second conductor layers by the first insulating seal;
the second active material layer having an outer side surface recessed relative to an outer side surface of the second conductor layer, leaving a second undercut area between the third conductor layer and the second conductor layer; and
a second insulating seal enclosing a second insulating void in the second undercut area between the second and third conductor layers.

8. The cell of claim 7, wherein the first insulating void in the undercut area surrounds the recessed active material-layer.

9. The cell of claim 7, wherein the first insulating void in the undercut area is surrounded by a portion of the insulating seal within the undercut area between the first and second conductor layers.

10. The cell of claim 7, wherein the first active material layer comprises a chalcogenide, and the first and second conductor layers comprise conductive material resistant to selective lateral etch of the chalcogenide.

11. The cell of claim 10, wherein the second conductor layer comprises titanium nitride or tantalum nitride.

12. The cell of claim 10, wherein the second conductor layer comprises carbon.

13. (canceled)

14. The cell of claim 7, wherein the first and second conductor layers comprise conductive material resistant to an etch chemistry selective for the active material layer.

15. An integrated circuit memory device, comprising:
an array of pillar-shaped memory cells, the pillar-shaped memory cells in the array comprising, respectively:
a stack including a first conductor layer, a first chalcogenide layer configured as a memory element, a second conductor layer, a second chalcogenide layer configured as a switch element and a third conductor layer in electrical series;
the first chalcogenide layer having an outside surface recessed relative to an outer side surface of the second conductor layer, leaving an undercut area between the second conductor layer and the first conductor layer;
a first insulating seal enclosing a first insulating void in the undercut area, the first insulating void being enclosed between the first and second conductor layers by the insulating seal;
the second chalcogenide layer having an outside surface recessed relative to an outer side surface of the second conductor layer, leaving an undercut area between the third conductor layer and the second conductor layer; and
a second insulating seal enclosing a second insulating void between the second and third conductor layers.

16. The device of claim 15, wherein the first insulating void in the undercut area surrounds the recessed first chalcogenide layer.

17. The device of claim 15, wherein the insulating void in the undercut area is surrounded by a portion of the insulating seal within the undercut area between the first and second conductor layers.

18. The device of claim 15, wherein the first and second conductor layers comprise conductive material resistant to selective lateral etch of the first and second chalcogenide layers.
